(19) United States
(12) Patent Application Publication
(10) Pub. No.: US 2026/0186537 A1
(43) Pub. Date: Jul. 2, 2026

(54) Flexible Display Device

(71) Applicant: LG Display Co., Ltd., Seoul (KR)

(72) Inventors: MiJin Han, Seoul (KR); SunBok Song, Gwangmyeong-si (KR); Daeyun Kim, Seoul (KR)

(21) Appl. No.: 19/412,544

(22) Filed: Dec. 8, 2025

(30) Foreign Application Priority Data
Dec. 30, 2024 (KR) 10-2024-0200541

(51) Int. Cl. G06F 1/16

(52) U.S. Cl. CPC G06F 1/1656; G06F 1/1652

(57) ABSTRACT

A display device comprises a display panel; a cover window disposed on one side of the display panel; and a back cover disposed on the other side of the display panel opposite to the cover window; wherein the back cover comprises a plurality of sub-back covers, and at least one sub-back cover of the plurality of sub-back covers does not overlap with the display panel in a stacking direction of the display panel and the back cover, and is coupled to the cover window.

### CROSS-REFERENCE TO RELATED APPLICATIONS

This application claims the priority of Korean Patent Application No. 10-2024-0200541 filed on December 30, 2024, in the Korean Intellectual Property Office, the disclosure of which is incorporated herein by reference.

### FIELD

The present disclosure relates to a flexible display device, and more particularly, to a flexible display device capable of performing a rollable or slidable operation.

### BACKGROUND

With the advancement of display technologies, there is an increasing interest in bendable or foldable flexible display devices. In particular, in the case of rollable or slidable flexible display devices, a screen may be unrolled by a user when necessary, or the screen may be accommodated by being rolled or slid when the screen is not used, which may improve spatial utilization.

The flexible display device generally includes a cover window, a display panel, and a back cover. The cover window protects the display panel, and the back cover supports the display panel. In particular, the back cover has a hole formed in an area that overlaps the display panel, such that the back cover may be curved along a roller when the display device operates.

### SUMMARY

An object to be achieved by the present disclosure is to provide a flexible display device capable of minimizing damage to a display panel by guiding stress, which is applied to a back cover, to a cover window.

Another object to be achieved by the present disclosure is to provide a flexible display device, in which a back cover is divided into a plurality of sub-back covers, that is, includes a plurality of sub-back covers, and a suitable bonding structure is applied to each sub-back cover of the back cover, thereby effectively dispersing stress occurring during an operation.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device comprises a display panel; a cover window disposed on one side of the display panel; and a back cover disposed on the other side of the display panel opposite to the cover window; wherein the back cover comprises a plurality of sub-back covers, and at least one sub-back cover of the plurality of sub-back covers doesn’t overlap with the display panel in a stacking direction of the display panel and the back cover, and is coupled to the cover window.

According to another aspect of the present disclosure, there is provided a display device. The display device comprises a display panel; a cover window disposed on one side of the display panel; and a back cover disposed on the other side of the display panel opposite to the cover window, wherein the back cover comprises: a first sub-back cover coupled to the cover window; a second sub-back cover coupled to the display panel; and a third sub-back cover coupled to the cover window, and wherein the first sub-back cover, the second sub-back cover, and the third sub-back cover are spaced apart from one another.

Other detailed matters of the exemplary embodiments are included in the detailed description and the drawings.

The flexible display device according to the embodiment of the present disclosure may guide the stress transmission route to the cover window through the bonding layer, thereby inhibiting the stress from being transmitted directly to the display panel.

The flexible display device according to the embodiment of the present disclosure may minimize damage to the display panel and extend the lifespan of the product.

According to the flexible display device according to the embodiment of the present disclosure, the back cover is divided into the first to third sub-back covers spaced apart from one another, which may inhibit the stress, which occurs during the rolling or sliding operation, from being concentrated on a particular portion.

According to the flexible display device according to the embodiment of the present disclosure, the bonding layer and the adhesive layer may have different modulus, the bonding layer having a high modulus may effectively support a mechanical load, and the adhesive layer having a low modulus may absorb stress that occurs when the display panel is transformed.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exploded perspective view of a flexible display device according to an embodiment of the present disclosure;

FIG. 2 is a cross-sectional view of the flexible display device according to the embodiment of the present disclosure;

FIG. 3 is a schematic view of a flexible display device according to another embodiment of the present disclosure;

FIG. 4 is a cross-sectional view of the flexible display device according to another embodiment of the present disclosure;

FIG. 5 is a schematic view illustrating a flexible display device according to still another embodiment of the present disclosure; and

FIG. 6 is a cross-sectional view of the flexible display device according to still another embodiment of the present disclosure.

### DETAILED DESCRIPTION OF THE EMBODIMENT

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” other element or layer, another element or layer may be disposed directly on the other element or layer or interposed therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Further, spatially relative terms, such as “beneath,” “below,” “bottom,” “above,” “upper,” “top,”and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations), and the spatially relative descriptors used herein may likewise be interpreted accordingly.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

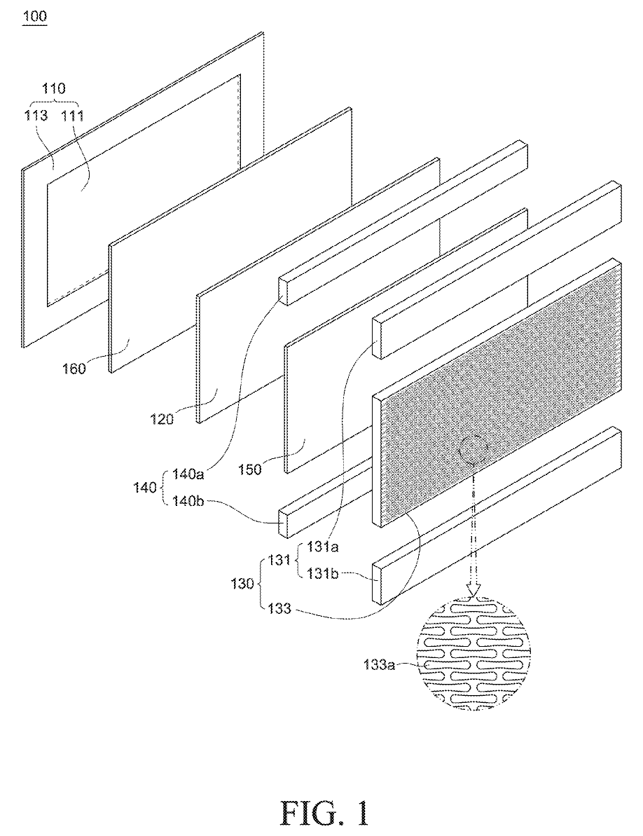

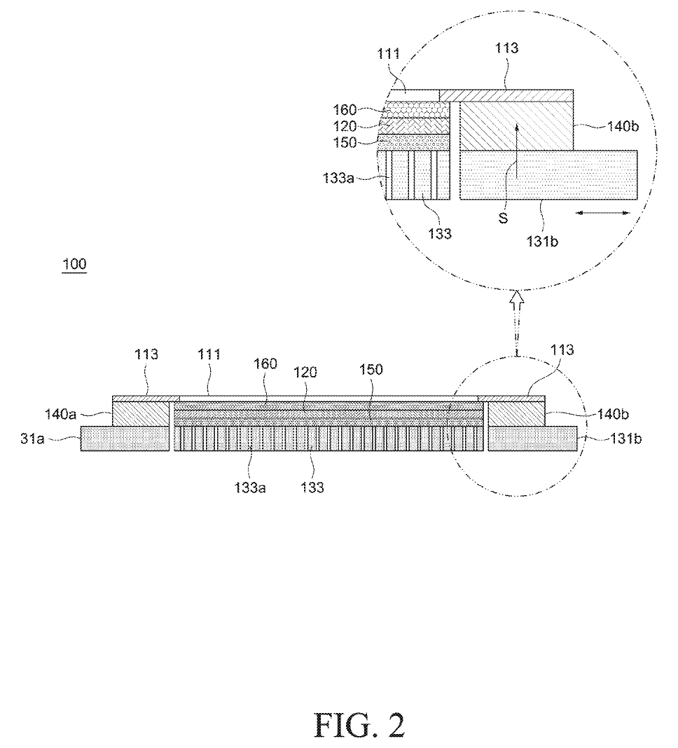

FIG. 1 is an exploded perspective view of a flexible display device according to an embodiment of the present disclosure. FIG. 2 is a cross-sectional view of the flexible display device according to the embodiment of the present disclosure.

With reference to FIGS. 1 and 2, a flexible display device 100 according to an embodiment of the present disclosure includes a cover window 110, a display panel 120, a back cover 130, a first bonding layer 140 including a first sub-bonding layer 140a and a second sub-bonding layer 140b, a second bonding layer 160, and an adhesive layer 150. However, the embodiments of the present disclosure are not limited thereto. For example, the first bonding layer 140 may also include other sub-bonding layers in addition to the first sub-bonding layer 140a and a second sub-bonding layer 140b.

The cover window 110 protects the display panel 120. The cover window 110 is disposed on the display panel 120 and protects the display panel 120 from external impact or scratches.

The cover window 110 may include a transparent area 111 and an opaque area 113.

The transparent area 111 of the cover window 110 may be positioned on a central portion of the cover window 110, but the embodiments of the present disclosure are not limited thereto. The transparent area 111 has light transmissivity so that images on the display panel 120 are visible to the outside. The transparent area 111 may be disposed to overlap a display area of the display panel 120.

In an embodiment, the opaque area 113 of the cover window 110 is positioned at an edge of the cover window 110. The opaque area 113 is formed to surround the transparent area 111. However, the embodiments of the present disclosure are not limited thereto. For example, the opaque area 113 may only be located on the upper and lower sides, or the left and right sides of the transparent area 111. The opaque area 113 may be disposed to overlap a non-display area of the display panel 120 and side back covers 131 of the back cover 130.

The display panel 120 is disposed below the cover window 110.

The display panel 120 is a panel configured to display images. In an embodiment, the display panel 120 may be any one of a plasma display panel, a liquid crystal display panel, an organic light-emitting diode display panel, and a light-emitting diode display panel.

The display panel 120 is disposed so that images are displayed to the outside through the transparent area 111 of the cover window 110. In an embodiment, the display panel 120 is disposed to overlap the transparent area 111 of the cover window 110, such that the image displayed on the display panel 120 is provided to a user through the transparent area 111 of the cover window 110.

In an embodiment, the second bonding layer 160 is disposed between the cover window 110 and the display panel 120. The second bonding layer 160 is a bonding layer used to bond the cover window 110 and the display panel 120. The second bonding layer 160 may be configured as a transparent bonding layer so that the image on the display panel 120 may be visually recognized. For example, the second bonding layer 160 may be an optical clear adhesive (OCA). However, the present disclosure is not limited thereto.

In an embodiment, the back cover 130 is disposed below the cover window 110 and the display panel 120 and supports the cover window 110 and the display panel 120. The back cover 130 may protect the display panel 120 from the outside. The back cover 130 may be made of a material having rigidity. For example, the back cover 130 may be made of a metallic material, such as stainless steel (steel use stainless (SUS)) or Invar, or a material such as plastic. However, the material of the back cover 130 may be variously changed in accordance with design as long as the material of the back cover 130 satisfies physical property conditions such as a thermal deformation amount, a radius of curvature, or rigidity. However, the present disclosure is not limited thereto.

In an embodiment, the back cover 130 includes the plurality of side back covers 131 and a mid-back cover 133 that are disposed below the cover window 110 and the display panel 120 and spaced apart from one another.

The plurality of side back covers 131 are each disposed to be spaced apart from the mid-back cover 133 and transmit stress S, which is generated during rolling and sliding operations, to the cover window 110. The plurality of side back covers 131 are disposed below the opaque area 113 of the cover window 110, and don’t overlap with the display panel in a stacking direction of the display panel and the back cover.

The plurality of side back covers 131 includes a first side back cover 131a and a second side back cover 131b.

The first side back cover 131a is disposed at one side of the mid-back cover 133, and the second side back cover 131b is disposed at the other side of the mid-back cover 133 opposite to the first side back cover 131a. In this case, the first side back cover 131a may be referred to as a first sub-back cover 131a, and the second side back cover 131b may be referred to as a third sub-back cover 131b.

The back cover 130 includes the mid-back cover 133 disposed between the plurality of side back covers 131. In this case, the mid-back cover 133 may be referred to as a second sub-back cover 133.

The mid-back cover 133 is disposed below the display panel 120. The mid-back cover 133 includes a plurality of holes 133a formed in an area that overlaps the display panel 120. The plurality of holes 133a allow the mid-back cover 133 to be curved along a roller. The mid-back cover 133 is coupled to the display panel 120 by means of the adhesive layer 150 and supports the display panel 120 when the display panel 120 is rolled or slid. The plurality of holes 133a are transformed in shapes when the display panel 120 is wound around the roller or slid along the roller. The mid-back cover 133 includes the plurality of holes 133a that may be transformed in shapes, such that the mid-back cover 133 has higher flexibility than the side back cover 131. The plurality of holes 133a enable the operations of rolling and sliding the mid-back cover 133.

In an embodiment, the plurality of sub-bonding layers of the first bonding layer 140 are disposed between the opaque area 113 of the cover window 110 and the plurality of side back covers 131, as shown in FIG. 1. The plurality of side back covers 131 are coupled to the cover window 110 by means of the plurality of sub-bonding layers. The plurality of sub-bonding layers of the first bonding layer 140 have high coupling forces and provide high structural supporting forces between the plurality of side back covers 131 and the opaque area 113 when the display panel 120 is rolled and slid.

The plurality of sub-bonding layers of the first bonding layer 140 include the first sub-bonding layer 140a and the sub-second bonding layer 140b. The first sub-bonding layer 140a is disposed between the cover window 110 and the first side back cover 131a, and the second sub-bonding layer 140b is disposed between the cover window 110 and the second side back cover 131b.

The adhesive layer 150 is disposed between the display panel 120 and the mid-back cover 133. The display panel 120 and the mid-back cover 133 are coupled by means of the adhesive layer 150. The adhesive layer 150 absorbs stress that occurs when the display panel 120 is transformed. The adhesive layer 150 may mitigate tensile stress and compressive stress that occur when the display panel 120 is rolled or slid. The adhesive layer 150 suppresses damage to the display panel 120 by mitigating stress applied to the display panel 120. The display panel 120 may be coupled onto the mid-back cover 133 by means of the adhesive layer 150, and the display panel 120 may stably display images even when the display panel 120 is operated by the roller.

The adhesive layer 150 is disposed to be spaced apart from the plurality of sub-bonding layers of the first bonding layer 140. Because the first bonding layer 140 and the adhesive layer 150 are disposed to be spaced apart from each other, the first side back cover 131a, the mid-back cover 133, and the second side back cover 131b may operate independently. The first side back cover 131a, the mid-back cover 133, and the second side back cover 131b may disperse stress applied to an overall structure while operating independently.

The plurality of sub-bonding layers of the first bonding layer 140 and the adhesive layer 150 are disposed at different positions and provide different functions.

The plurality of sub-bonding layers of the first bonding layer 140 securely couple the opaque area 113 of the cover window 110 and the side back covers 131. The secure coupling provided by the plurality of sub-bonding layers effectively supports a mechanical load that occurs during the operations of rolling and sliding the flexible display device 100.

The plurality of sub-bonding layers of the first bonding layer 140 may each have a modulus higher than a modulus of the adhesive layer 150. The modulus refers to a physical quantity that indicates rigidity of a material. A high modulus may refer to high rigidity, and a low modulus may refer to flexibility.

The adhesive layer 150 has a relatively lower modulus than the plurality of sub-bonding layers. The adhesive layer 150 enables the display panel 120 and the mid-back cover 133 to move flexibly when the display panel 120 is curved along the roller with a predetermined curvature.

According to the flexible display device 100 according to the embodiment of the present disclosure, the first bonding layer 140 may have a modulus of 10⁸ Pa or more. The adhesive layer 150 may have a modulus of 10⁴ Pa to 10⁶ Pa.

The first sub-bonding layer 140a and the second sub-bonding layer 140b according to the embodiment of the present disclosure may each have a relatively high modulus of 10⁸ Pa to 10¹² Pa. The high modulus of the first sub-bonding layer 140a and second sub-bonding layer 140b enable the cover window 110 and the side back cover 131 to be securely coupled. Specifically, the modulus within a range of 10⁸ Pa to 10¹² Pa provides strength capable of sufficiently supporting a mechanical load that occurs when the flexible display device 100 operates. When the modulus of the first sub-bonding layer 140a and the second sub-bonding layer 140b of the first bonding layer 140 is lower than 10⁸ Pa, the structural stability may be insufficient. When the modulus of the first sub-bonding layer 140a and the second sub-bonding layer 140b is higher than 10¹² Pa, the brittleness rather may increase, and the bonding reliability may deteriorate.

The adhesive layer 150 may have a relatively low modulus of 10⁴ Pa to 10⁶ Pa. The adhesive layer 150 has a relatively low modulus and may provide flexibility required when the display panel 120 is curved along the roller with a predetermined curvature. The modulus within the range of 10⁴ Pa to 10⁶ Pa may enable the display panel 120 and the mid-back cover 133 to move freely, and the modulus may simultaneously maintain a bonding force between the display panel 120 and the mid-back cover 133. When the modulus of the adhesive layer 150 is lower than 10⁴ Pa, it may be difficult to ensure a sufficient bonding force. When the modulus of the adhesive layer 150 is higher than 10⁶ Pa, it may be difficult to ensure necessary flexibility.

The first bonding layer 140 and the adhesive layer 150 may be made of acrylic resin, epoxy resin, or silicone resin. Acrylic resin, epoxy resin, or silicone resin each have unique properties. Acrylic resin, epoxy resin, or silicone resin may be selectively applied to the first bonding layer 140 and the adhesive layer 150 depending on the requirement of the flexible display device 100.

The acrylic resin may provide excellent transparency and weather resistance and stably maintains the bonding force. In an embodiment, the acrylic resin may be applied to both the first bonding layer 140 and the adhesive layer 150 because the acrylic resin may widely adjust the modulus. The acrylic resin with high modulus may be suitable for the first bonding layer 140, and the acrylic resin with low modulus may be suitable for the adhesive layer 150.

The epoxy resin has a high bonding force and excellent mechanical strength. The epoxy resin may be particularly suitable for the first bonding layer 140. Because the epoxy resin has a high modulus after being cured, the epoxy resin may provide the secure coupling between the cover window 110 and the back cover 130. The epoxy resin is excellent in heat resistance and moisture resistance, such that the epoxy resin may maintain stable bonding performance even under various environmental conditions.

The silicone resin has excellent flexibility and elasticity and excellent stability with respect to a change in temperature. Because the silicone resin may have a low modulus, the silicone resin may be suitable as a material for the adhesive layer 150. The silicone resin may effectively mitigate stress that occurs when the display panel 120 is rolled or slid.

As described above, because acrylic resin, epoxy resin, or silicone resin has advantages, an optimal material may be selected depending on a particular part of the flexible display device 100 and the required physical properties. In addition, even resins based on the same series may have various modulus depending on compositions thereof and manufacturing conditions, which may precisely satisfy the required characteristics of the first bonding layer 140 and the adhesive layer 150.

In a general flexible display device, the back cover is integrated. That is, the back cover is not divided, and a part of the back cover, which is coupled to the cover window, and a part of the back cover, which is coupled to the display panel, are integrated. For this reason, there is a problem in that the stress, which is applied to the back cover during the operation of the flexible display device, is transmitted to the display panel, which causes damage to the display panel. In addition, the stress, which is applied to the back cover during the operation of the flexible display device, is transmitted to the entire display panel, which causes a problem in that an adhesive force between the display panel and the back cover is decreased, and the display panel and the back cover are separated.

In the flexible display device 100 according to the embodiment of the present disclosure, the back cover 130 is divided into the plurality of side back covers 131 and the mid-back cover 133 disposed to be spaced apart from one another. Therefore, the flexible display device 100 according to the embodiment of the present disclosure may inhibit the stress, which occurs during the operation of the flexible display device, from being transmitted to the entire display panel 120. In particular, the mid-back cover 133 may ensure the flexibility of the display panel 120, and the plurality of side back covers 131 may maintain the structural stability.

In the flexible display device 100 according to the embodiment of the present disclosure, the adhesive layer 150, which has a lower modulus than the first bonding layer 140 disposed between the opaque area 113 of the cover window 110 and the plurality of side back covers 131, is disposed between the display panel 120 and the mid-back cover 133. Therefore, in the flexible display device 100 according to the embodiment of the present disclosure, the structure stability may be improved by inhibiting the display panel 120, the cover window 110, and the like from slipping.

In the flexible display device 100 according to the embodiment of the present disclosure, the bonding structure, which is differentiated from the structure in which the back cover 130 is divided, may effectively suppress a decrease in the adhesive force or damage to the display panel 120 that may occur when the flexible display device 100 is rolled or slid.

In the flexible display device 100 according to the embodiment of the present disclosure, the stress S, which is applied to the plurality of side back covers 131 when the flexible display device 100 moves while being guided by the roller, is transmitted directly to the cover window 110 through the first bonding layer 140, which may inhibit the stress S from being transmitted directly to the display panel 120. Therefore, it is possible to minimize damage to the display panel 120 and improve reliability of products.

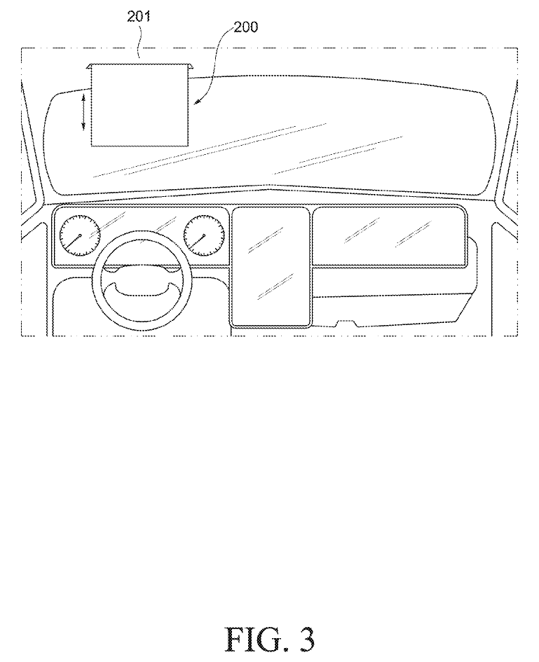

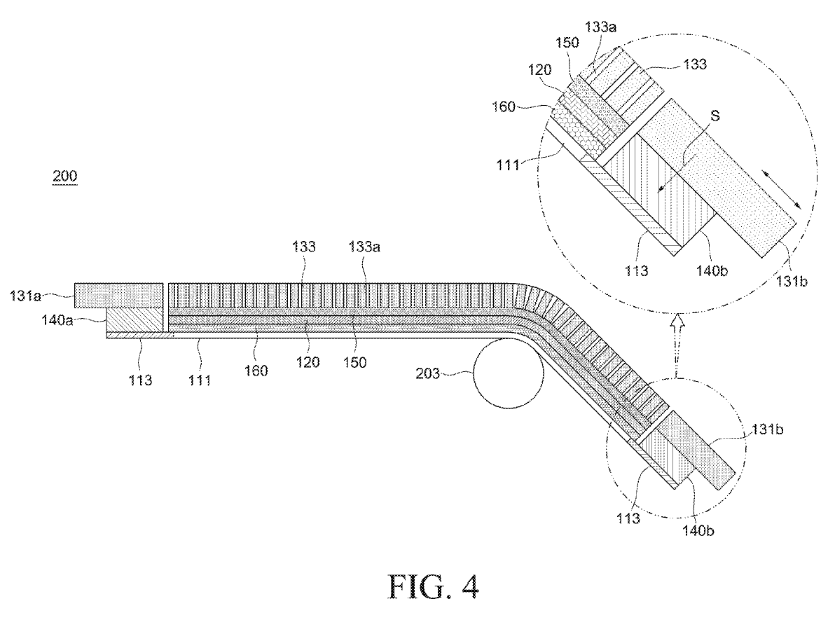

FIG. 3 is a schematic view of a flexible display device according to another embodiment of the present disclosure. FIG. 4 is a cross-sectional view of the flexible display device according to another embodiment of the present disclosure.

With reference to FIGS. 3 and 4, a flexible display device 200 according to another embodiment of the present disclosure may be implemented as a slidable display device and installed in an interior of a vehicle. Specifically, the flexible display device 200 according to another embodiment of the present disclosure may be implemented as a slidable display device and installed in a ceiling in a vehicle body. However, the present disclosure is not limited thereto. The flexible display device 200 may be installed at another position instead of being installed in the vehicle body.

The flexible display device 200 according to another embodiment of the present disclosure may further include a housing 201 and a roller 203 in addition to the flexible display device 100 according to the embodiment of the present disclosure described with reference to FIGS. 1 and 2. The housing 201 is disposed in the ceiling in the vehicle body, and the components of the flexible display device 100 and the roller 203 are installed in an internal space of the housing 201.

When the user, who is a driver or a fellow passenger in an auxiliary seat, slides the flexible display device 200 in an upward/downward direction, the main components, i.e., the cover window 110, the display panel 120, and the back cover 130 of the flexible display device 200 may be moved in one direction or the other direction. The user may move the main components of the flexible display device 200 by applying a force to the side back cover 131 of the flexible display device 200. Alternatively, the flexible display device 200 according to the embodiment may further include a drive device coupled to the side back cover 131. When the side back cover 131 is pressed in one direction by an operation of the drive device, the main components of the flexible display device 200 may be moved.

Any one of the plurality of side back covers 131, e.g., the first side back cover 131a may be disposed inside the housing 201 in the ceiling of the vehicle, and another of the plurality of side back covers 131, e.g., the second side back cover 131b may be disposed outside the housing 201.

The second side back cover 131b is moved in one direction by an external force applied by the user or the drive device, so as to slide the display panel 120 and the mid-back cover 133 along the roller 203. The stress S, which is applied to the second side back cover 131b when the second side back cover 131b is moved in one direction by the external force, is transmitted to the cover window 110 through the second sub-bonding layer 140b.

The roller 203 of the flexible display device 200 according to another embodiment of the present disclosure guides the movement of the display panel 120. The roller 203 determines a movement route for the display panel 120 when the display panel 120 is slid along the roller 203.

The roller 203 has a predetermined curvature. In one embodiment, the roller 203 may have a curvature of 30R. However, the present disclosure is not limited thereto. The display panel 120 and the mid-back cover 133 each move along the roller 203 with a curvature corresponding to a curvature of the roller 203. The display panel 120 and the mid-back cover 133 each moves while being curved with a curvature corresponding to the curvature of the roller 203 when the display panel 120 and the mid-back cover 133 slide along the roller 203, as illustrated in FIGS. 3 and 4.

When the display panel 120 and the mid-back cover 133 slide along the roller 203 with the curvature corresponding to the curvature of the roller 203, the mechanical stress S is applied to the first side back cover 131a or the second side back cover 131b by the operation of the drive device or the pressing operation of the user. In the flexible display device 200 according to another embodiment of the present disclosure, the mechanical stress S applied to the first side back cover 131a and the second side back cover 131b is transmitted to the cover window 110, such that the stress S is effectively controlled. The first side back cover 131a and the second side back cover 131b define routes along which the stress S, which occurs during the operation, is transmitted to the cover window 110 through the first bonding layer 140. The stress S, which is applied to the first side back cover 131a or the second side back cover 131b when the display panel 120 moves along the roller 203, is transmitted to the cover window 110 through the first bonding layer 140.

The transmission route for the stress S will be described. First, the stress S is applied to the first side back cover 131a or the second side back cover 131b when the display panel 120 moves by being guided by the roller 203. In one embodiment, the first side back cover 131a or the second side back cover 131b may be connected to the drive device configured to slide the display panel 120 and the mid-back cover 133 on the roller 203. As the first side back cover 131a or the second side back cover 131b is moved in one direction by the operation of the drive device, the stress S is applied to the first side back cover 131a or the second side back cover 131b. The stress S applied to the first side back cover 131a or the second side back cover 131b is transmitted to the cover window 110 through the first bonding layer 140. The first side back cover 131a or the second side back cover 131b is disposed to be spaced apart from the mid-back cover 133 and inhibits the stress S from being transmitted directly to the display panel 120.

With this structure, the flexible display device 200 according to another embodiment of the present disclosure may perform the stable sliding operation, protect the display panel 120, and more easily disperse the stress S.

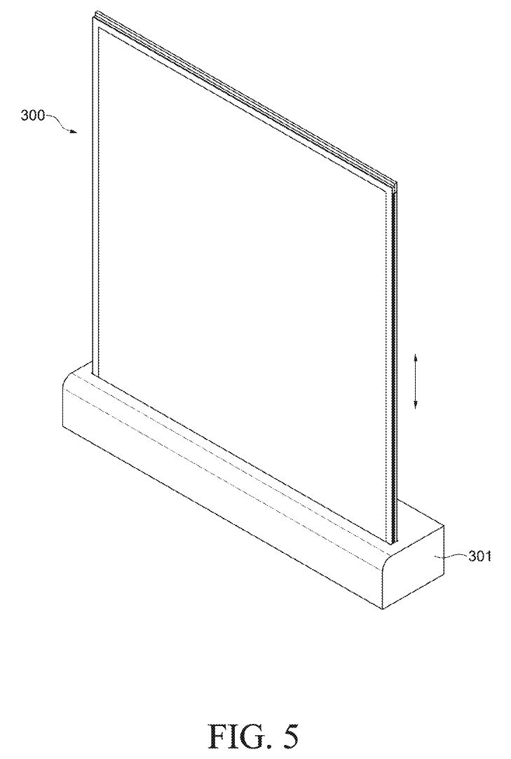

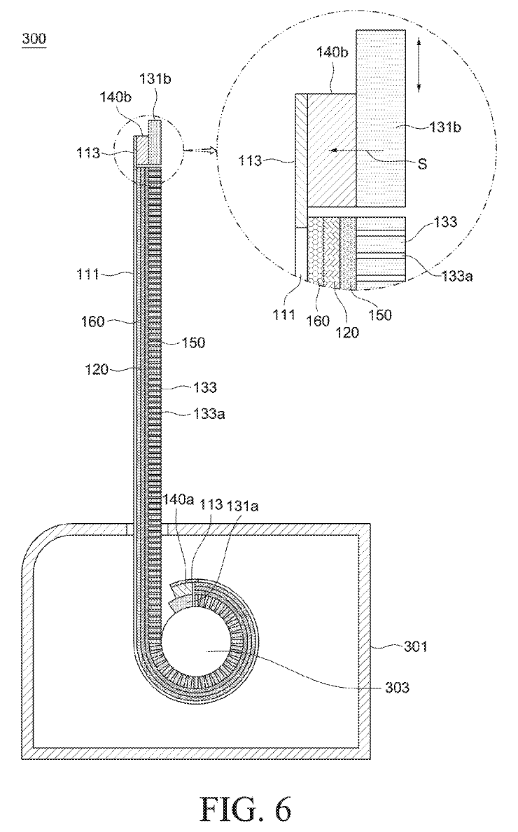

FIG. 5 is a schematic view illustrating a flexible display device according to still another embodiment of the present disclosure. FIG. 6 is a cross-sectional view of the flexible display device according to still another embodiment of the present disclosure.

With reference to FIGS. 5 and 6, a flexible display device 300 according to still another embodiment of the present disclosure may be a flexible display device 300 having a rollable shape applied to a large-scale display such as a TV.

The flexible display device 300 according to still another embodiment of the present disclosure may further include a housing 301 and a roller 303 in addition to the above-mentioned flexible display device 100.

The flexible display device 300 according to still another embodiment of the present disclosure has a structure in which the display panel 120 is wound around or unwound from the roller 303 installed in the housing 301.

The roller 303 guides the display panel 120 and the mid-back cover 133 so that the display panel 120 and the mid-back cover 133 are wound with a predetermined curvature. The housing 301 provides a space that may accommodate the components of the flexible display device 100, the roller 303, and the like.

In the flexible display device 300 according to still another embodiment of the present disclosure, the first side back cover 131a or the second side back cover 131b moves by being pressed in one direction by the operation of the drive device connected to the first side back cover 131a or the second side back cover 131b during the rolling operation. In this case, when the roller 303 rotates, the display panel 120 and the mid-back cover 133 are wound around or unwound from the roller 303. The stress S is applied to the first side back cover 131a or the second side back cover 131b by the operation of the drive device or the operation of the user, and the stress S is transmitted to the cover window 110 through the first sub-bonding layer 140a or the second sub-bonding layer 140b.

Any one of the first side back cover 131a and the second side back cover 131b, e.g., the first side back cover 131a may be coupled to the roller 303 in the housing 301, and the other of the first side back cover 131a and the second side back cover 131b, e.g., the second side back cover 131b may be disposed outside the housing 301.

The second side back cover 131b is moved in one direction by an external force, so as to roll the display panel 120 and the mid-back cover 133 along the roller 303. The stress S, which is applied to the second side back cover 131b when the second side back cover 131b is moved in one direction by the external force, is transmitted to the cover window 110 through the second sub-bonding layer 140b.

The user may move the main components of the flexible display device 300 upward by pressing the second side back cover 131b, which is disposed outside the housing 301, upward. Alternatively, when the second side back cover 131b is pressed upward by the operation of the drive device coupled to the second side back cover 131b, the main components of the flexible display device 300 may be moved upward. In this case, the stress S is applied to the second side back cover 131b by a force applied by the user or the operation of the drive device, and the stress S is transmitted to the cover window 110 through the second sub-bonding layer 140b.

The roller 303 of the flexible display device 300 according to still another embodiment of the present disclosure guides the movement of the display panel 120. The roller 303 determines a movement route for the display panel 120 when the display panel 120 is rolled along the roller 303.

The roller 303 has a predetermined curvature. In one embodiment, the roller 303 may have a curvature of 30R. However, the present disclosure is not limited thereto. The display panel 120 and the mid-back cover 133 each move along the roller 303 with a curvature corresponding to a curvature of the roller 303.

When the display panel 120 and the mid-back cover 133 are rolled along the roller 303 with the curvature corresponding to the curvature of the roller 303, the mechanical stress S is applied to the side back cover 131 by the operation of the drive device or the pressing operation of the user. In the flexible display device 300 according to still another embodiment of the present disclosure, the mechanical stress S applied to the first side back cover 131a and the second side back cover 131b is transmitted to the cover window 110, such that the stress S is effectively controlled. The first side back cover 131a and the second side back cover 131b define routes along which the stress S, which occurs during the operation, is transmitted to the cover window 110 through the first bonding layer 140. The stress S, which is applied to the side back cover 131 when the display panel 120 moves along the roller 303, is transmitted to the cover window 110 through the first bonding layer 140.

The transmission route for the stress S will be described. First, the stress S is applied to the second side back cover 131b when the display panel 120 moves by being guided by the roller 303. In one embodiment, the second side back cover 131b may be connected to the drive device configured to roll the display panel 120 and the mid-back cover 133 along the roller 303. As the second side back cover 131b is moved in one direction by the operation of the drive device, the stress S is applied to the first side back cover 131a and the second side back cover 131b. The stress S applied to the first side back cover 131a and the second side back cover 131b is transmitted to the cover window 110 through the first bonding layer 140.

With the above-mentioned configuration, the flexible display device 300 according to still another embodiment of the present disclosure may efficiently accommodate and deploy a large-scale display, protect the display panel 120, and easily disperse the stress S during the operation.

The greatest advantage of the structure for transmitting the stress S in the flexible display devices 100, 200, and 300 according to the present disclosure is to protect the display panel 120 from the stress S that occurs when the display panel 120 is rolled or slid. Because the display panel 120 is a key component that displays images, the display panel 120 needs to be protected from excessive stress S. The structure for transmitting the stress S in the flexible display devices 100, 200, and 300 according to the present disclosure transmits the stress S to the cover window 110 through the first bonding layer 140, such that the display panel 120 receives only the minimum stress required for bending.

As a result, the combination of the mechanism for transmitting the stress S and the structure for operating the rollers 203 and 303 in the flexible display devices 100, 200, and 300 according to the present disclosure may significantly contribute to improving the stable operation and durability of the flexible display devices 100, 200, and 300.

The exemplary embodiments of the present disclosure can also be described as follows:

According to an aspect of the present disclosure, there is provided a display device. The display device comprises a display panel; a cover window disposed on one side of the display panel; and a back cover disposed on the other side of the display panel opposite to the cover window; wherein the back cover comprises a plurality of sub-back covers, and at least one sub-back cover of the plurality of sub-back covers doesn’t overlap with the display panel in a stacking direction of the display panel and the back cover, and is coupled to the cover window.

The display device further comprises a first bonding layer, wherein the at least one sub-back cover may be coupled to the cover window through the first bonding layer.

The at least one sub-back cover may comprise a first side back cover and a second side back cover, and the first bonding layer may comprise a first sub-bonding layer and a second sub-bonding layer. The first side back cover may be coupled to the cover window through the first sub-bonding layer, and the second side back cover is coupled to the cover window through the second sub-bonding layer.

The cover window may include a transparent area and an opaque area, wherein the first side back cover is coupled to the opaque area of the cover window through the first sub-bonding layer, and the second side back cover is coupled to the opaque area of the cover window through the second sub-bonding layer.

The display device further comprises a first adhesive layer which is disposed between the first sub-bonding layer and the second sub-bonding layer and is spaced apart from the first sub-bonding layer and the second sub-bonding layer.

The plurality of sub-back covers may further comprise a mid-back cover, wherein the mid-back cover is between the first side back cover and the second side back cover, and is coupled to the display panel through the first adhesive layer.

The first side back cover, the second side back cover and the mid-back cover may be spaced apart from each other in a direction perpendicular to the stacking direction.

The mid-back cover may comprise a plurality of holes.

A modulus of the first bonding layer may be higher than that of the first adhesive layer.

The display device further comprises the second bonding layer configured as a transparent bonding layer, wherein the cover window is coupled to the display panel through the second bonding layer.

A sum of thicknesses of the first adhesive layer, the display panel and the second bonding layer may be the same as the thickness of the first bonding layer.

The first bonding layer may be made of epoxy resin, or acrylic resin with high modulus, and the first adhesive layer may be made of silicone resin, or acrylic resin with low modulus.

According to an aspect of the present disclosure, there is provided a display device. The display device comprises a display panel; a cover window disposed on one side of the display panel; and a back cover disposed on the other side of the display panel opposite to the cover window, wherein the back cover comprises: a first sub-back cover coupled to the cover window; a second sub-back cover coupled to the display panel; and a third sub-back cover coupled to the cover window, and wherein the first sub-back cover, the second sub-back cover, and the third sub-back cover are spaced apart from one another.

The display device further may comprise a first sub-bonding layer disposed between the cover window and the first sub-back cover; an adhesive layer disposed between the display panel and the second sub-back cover; and a second sub-bonding layer disposed between the cover window and the third sub-back cover.

The first sub-bonding layer and the second sub-bonding layer each may have a modulus higher than a modulus of the adhesive layer.

A modulus of each of the first sub-bonding layer and the second sub-bonding layer may be 10⁸ Pa to 10¹² Pa, and a modulus of the adhesive layer may be 10⁴ Pa to 10⁶ Pa.

The first sub-bonding layer and the second sub-bonding layer may be made of epoxy resin, or acrylic resin with high modulus, and the adhesive layer may be made of silicone resin, or acrylic resin with low modulus.

The display device further comprises a roller configured to guide a movement route for the display panel, wherein the display panel and the second sub-back cover are rolled around the roller or slid along the roller.

The first sub-back cover or the third sub-back cover transmits stress, which occurs when moving by being guided by the roller, to the cover window through the first sub-bonding layer or the second sub-bonding layer.

The second sub-back cover comprises a plurality of holes formed in an area that overlaps the display panel.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the appended claims, and all the technical concepts in the equivalent scope thereof should be construed as falling within the scope of the present disclosure.

What is claimed is:

1. A display device, comprising:
a display panel;
a cover window disposed on one side of the display panel; and
a back cover disposed on the other side of the display panel opposite to the cover window,
wherein the back cover comprises a plurality of sub-back covers, and at least one sub-back cover of the plurality of sub-back covers does not overlap with the display panel in a stacking direction of the display panel and the back cover, and is coupled to the cover window.

2. The display device according to claim 1, further comprising a first bonding layer, wherein the at least one sub-back cover is coupled to the cover window through the first bonding layer.

3. The display device according to claim 2,
wherein the at least one sub-back cover comprises a first side back cover and a second side back cover,
wherein the first bonding layer comprises a first sub-bonding layer and a second sub-bonding layer, and
wherein the first side back cover is coupled to the cover window through the first sub-bonding layer, and the second side back cover is coupled to the cover window through the second sub-bonding layer.

4. The display device according to claim 3, wherein the cover window includes a transparent area and an opaque area, wherein the first side back cover is coupled to the opaque area of the cover window through the first sub-bonding layer, and the second side back cover is coupled to the opaque area of the cover window through the second sub-bonding layer.

5. The display device according to claim 3, further comprising a first adhesive layer which is disposed between the first sub-bonding layer and the second sub-bonding layer and is spaced apart from the first sub-bonding layer and the second sub-bonding layer.

6. The display device according to claim 5, wherein the plurality of sub-back covers further comprise a mid-back cover, wherein the mid-back cover is between the first side back cover and the second side back cover, and is coupled to the display panel through the first adhesive layer.

7. The display device according to claim 6, wherein the first side back cover, the second side back cover and the mid-back cover are spaced apart from each other in a direction perpendicular to the stacking direction.

8. The display device according to claim 6, wherein the mid-back cover comprises a plurality of holes.

9. The display device according to claim 5, wherein a modulus of the first bonding layer is higher than a modulus of the first adhesive layer.

10. The display device according to claim 5, further comprising a second bonding layer configured as a transparent bonding layer, wherein the cover window is coupled to the display panel through the second bonding layer.

11. The display device according to claim 10, wherein a sum of thicknesses of the first adhesive layer, the display panel and the second bonding layer is the same as a thickness of the first bonding layer.

12. The display device according to claim 5, wherein
the first bonding layer is made of epoxy resin, or acrylic resin with high modulus, and
the first adhesive layer is made of silicone resin, or acrylic resin with low modulus.

13. A display device comprising:
a display panel;
a cover window disposed on one side of the display panel; and
a back cover disposed on the other side of the display panel opposite to the cover window,
wherein the back cover comprises:
a first sub-back cover coupled to the cover window;
a second sub-back cover coupled to the display panel; and
a third sub-back cover coupled to the cover window, and
wherein the first sub-back cover, the second sub-back cover, and the third sub-back cover are spaced apart from one another.

14. The display device of claim 13, further comprising:
a first sub-bonding layer disposed between the cover window and the first sub-back cover;
an adhesive layer disposed between the display panel and the second sub-back cover; and
a second sub-bonding layer disposed between the cover window and the third sub-back cover.

15. The display device of claim 14, wherein the first sub-bonding layer and the second sub-bonding layer each has a modulus higher than a modulus of the adhesive layer.

16. The display device of claim 15, wherein a modulus of each of the first sub-bonding layer and the second sub-bonding layer is 10⁸ Pa to 10¹² Pa, and a modulus of the adhesive layer is 10⁴ Pa to 10⁶ Pa.

17. The display device of claim 14, wherein
the first sub-bonding layer and the second sub-bonding layer are made of epoxy resin, or acrylic resin with high modulus, and
the adhesive layer is made of silicone resin, or acrylic resin with low modulus.

18. The display device of claim 14, further comprising:
a roller configured to guide a movement route for the display panel,
wherein the display panel and the second sub-back cover are rolled around the roller or slid along the roller.

19. The display device of claim 18, wherein the first sub-back cover or the third sub-back cover transmits stress, which occurs when moving by being guided by the roller, to the cover window through the first sub-bonding layer or the second sub-bonding layer.

20. The display device of claim 13, wherein the second sub-back cover comprises a plurality of holes formed in an area that overlaps the display panel.
